(19) United States
(12) Patent Application Publication
(10) Pub. No.: US 2013/0078787 A1
(43) Pub. Date: Mar. 28, 2013

(54) METHOD FOR MANUFACTURING SEMICONDUCTOR DEVICE

(71) Applicants: Hiroshi Nakatsuji, Osaka (JP); Kazushige Hotta, Osaka (JP); Naoki Makita, Osaka (JP)

(72) Inventors: Hiroshi Nakatsuji, Osaka (JP); Kazushige Hotta, Osaka (JP); Naoki Makita, Osaka (JP)

(73) Assignee: SHARP KABUSHIKI KAISHA, Osaka (JP)

(21) Appl. No.: 13/702,758

(22) PCT Filed: May 16, 2011
(86) PCT No.: PCT/JP2011/002707

§ 371 Date: Dec. 12, 2012

(30) Foreign Application Priority Data
Jun. 9, 2010 (JP) 2010-132461

(51) Int. Cl. H01L 21/04

(52) U.S. Cl. CPC H01L 21/04
USPC 438/510

(57) ABSTRACT

Disclosed is a method for manufacturing a semiconductor device, including the steps of: forming a first semiconductor film (2) and a second semiconductor film (4) over a glass substrate (6); forming a photosensitive resin over the glass substrate (6) to cover the first semiconductor film (2) and the second semiconductor film (4); conducting an exposure process in which controlled amounts of exposure radiation are projected to the photosensitive resin using a photomask; conducting a developing process on the photosensitive resin that was subjected to the exposure process, to form a first resist (40) over the first semiconductor film (2) and to form a second resist (41) over the second semiconductor film (4); implanting an n-type impurity into the first semiconductor film (2) using the first resist (40) and the second resist (41) as masks; and removing the first resist (40) and implanting a p-type impurity into the first semiconductor film (2) using the second resist (41) as a mask.

### TECHNICAL FIELD

The present invention relates to a method for manufacturing a semiconductor device.

### BACKGROUND ART

In recent years, liquid crystal display devices are generally used as screens of personal computers and televisions, for example. Further, liquid crystal display devices are also in wide use as screens of PDA (Personal Digital Assistant) and the like. Research and development are also underway on organic EL display devices, which can be more energy efficient than liquid crystal display devices. Organic EL display devices are already used in some products.

Liquid crystal display devices and organic EL display devices can be largely categorized into a passive matrix system and an active matrix system, depending on the drive method. In particular, compared to the passive matrix system, the active matrix system can realize a fast response and low-voltage drive, and therefore has been a hot subject of research and development.

Normally, display devices of active matrix system include a plurality of pixels disposed in a matrix, where each of the pixels include a thin film transistor (hereinafter also referred to as TFT) switching element.

A TFT includes a semiconductor film formed on a substrate having insulating properties, a gate insulating film formed on the semiconductor film, and a gate electrode formed on the gate insulating film. In the case of bottom gate type TFTs, the locations of the gate electrode and of the semiconductor film are opposite.

Because the carrier mobility of amorphous silicon is relatively low, when the semiconductor film is formed of an amorphous silicon, an IC (Integrated Circuit) for driving the display device needs to be connected outside the display panel to drive the display device with this driver IC.

On the other hand, because the carrier mobility of polysilicons is relatively high, when the semiconductor film is formed of a polysilicon, a driver circuit constituted of TFTs can be integrally formed on the display panel.

On the semiconductor film formed of a polysilicon, a source region and a drain region, which are a pair of high-concentration impurity regions into which a p-type impurity or an n-type impurity have been implanted using a gate electrode as a mask, are formed.

As semiconductor devices constituting a driver circuit for a display device such as a liquid crystal display device or the like, CMOS (Camplimentary Metal Oxide Semiconductor) including a p-type TFT and an n-type TFT is used. In the p-type TFT and the n-type TFT, if, for example, the semiconductor film is made of a polysilicon and the gate insulating film is made of a silicon oxide film, the threshold voltage becomes negative (approx. minus several volts) if no impurity is implanted into the channel region of the semiconductor film. As a result, the p-type TFT and the n-type TFT do not turn OFF when the gate electrode voltage (hereinafter referred to as gate voltage) is 0V, causing a leakage current (OFF current), which increases the power consumption.

Therefore, normally, a p-type impurity such as boron is implanted (doped) into the entire semiconductor film to control the threshold voltage so that OFF current does not flow into either the p-type TFT or the n-type TFT (see Patent Document 1, for example).

### RELATED ART DOCUMENTS

### Patent Documents

Patent Document 1: Japanese Patent Application Laid-Open Publication No. 2000-196096

### SUMMARY OF THE INVENTION

### Problems to be Solved by the Invention

However, the method of manufacturing according to Patent Document 1 has a problem. That is, in the n-type TFT formation process, separate photomasks have to be used when implanting an n-type impurity such as phosphorus into the source region and the drain region of the n-type TFT and when implanting a p-type impurity such as boron, which is mentioned above, into the channel region of the n-type TFT. This method increases the number of processes required to produce n-type TFTs and increases the cost.

The present invention was devised in consideration of the problems described above, and is aiming at providing a method for manufacturing a semiconductor in which the number of processes required to manufacture n-type TFTs can be reduced and the cost can be lowered.

### Means for Solving the Problems

In order to achieve the objectives described above, a first method for manufacturing a semiconductor device of the present invention is a method for manufacturing a semiconductor device having, on a substrate, an n-type thin film transistor including a first semiconductor film and a p-type thin film transistor including a second semiconductor film, including: conducting a semiconductor film formation process in which the first semiconductor film and the second semiconductor film are formed on the substrate; conducting a photosensitive resin formation process in which a photosensitive resin is formed over the substrate to cover the first semiconductor film and the second semiconductor film; conducting an exposure process in which controlled amounts of exposure radiation are projected to the photosensitive resin using a photomask; conducting a resist formation process in which a developing process is performed on the photosensitive resin that has been subjected to the exposure process, to form a first resist over the first semiconductor film and to form a second resist over the second semiconductor film; conducting an n-type impurity implantation process in which an n-type impurity is implanted into the first semiconductor film using the first resist and the second resist as masks; and conducting a p-type impurity implementation process in which the first resist is removed, and then, a p-type impurity is implanted into the first semiconductor film using the second resist as a mask.

According to this configuration, in the process of manufacturing an n-type thin film transistor, the first resist and the second resist, which are formed with a single photomask, can be used as masks when conducting the n-type impurity implantation process where an n-type impurity is implanted into the first semiconductor film of the n-type thin film transistor, and the p-type impurity implantation process where a p-type impurity is implanted into the first semiconductor film. As a result, there is no need to use two separate masks to conduct the n-type impurity implantation process and the p-type impurity implantation process, and only a single photomask needs to be used. Therefore, the number of processes required to manufacture an n-type thin film transistor can be reduced, and the manufacturing cost can significantly be lowered.

The first method for manufacturing the semiconductor device of the present invention may further include the step of conducting an insulating film formation process in which, after the p-type impurity implantation process, the second resist is removed and an insulating film is formed over the first semiconductor film and the second semiconductor film.

According to this configuration, an insulating film is formed after the p-type impurity implantation. Therefore, when ashing, for example, is conducted to remove the first resist, and a p-type impurity is implanted into the first semiconductor film using the second resist as a mask, where the second resist has a thickness that has been reduced by the ashing, the p-type impurity can be sufficiently implanted into the first semiconductor film without causing the problem of the p-type impurity implantation into the second semiconductor film due to the reduced thickness of the second resist.

In the first method for manufacturing the semiconductor device according to the present invention, a gray-tone mask or a half-tone mask may be used as the photomask.

According to this configuration, because exposure processes with different amounts of exposure radiation can easily be conducted on the photosensitive resin, controlled exposure radiation on the photosensitive resin becomes easy.

In the first method for manufacturing the semiconductor device of the present invention, the photosensitive resin may be an acrylic photosensitive resin.

In the first method for manufacturing the semiconductor device of the present invention, the first semiconductor film and the second semiconductor film may be formed of polysilicon.

A second method for manufacturing a semiconductor device of the present invention is a method for manufacturing a semiconductor device having, on a substrate, an n-type thin film transistor including a first semiconductor film, a p-type thin film transistor including a second semiconductor film, another n-type thin film transistor including a third semiconductor film, and a capacitance including a fourth semiconductor film, including: conducting a semiconductor film formation process in which the first semiconductor film, the second semiconductor film, the third semiconductor film, and the fourth semiconductor film are formed on the substrate; conducting a photosensitive resin formation process in which a photosensitive resin is formed over the substrate to cover the first semiconductor film, the second semiconductor film, the third semiconductor film, and the fourth semiconductor film; conducting an exposure process in which controlled amounts of exposure radiation are projected to the photosensitive resin using a photomask; conducting a resist formation process in which a developing process is performed on the photosensitive resin that has been subjected to the exposure process, to form a first resist over the first semiconductor film, to form a second resist over the second semiconductor film, and to form a third resist over the third semiconductor film; conducting an n-type impurity implantation process in which an n-type impurity is implanted into the first semiconductor film and the third semiconductor film using the first resist, the second resist, and the third resist as masks; and conducting a p-type impurity implantation process in which the first resist and the third resist are removed, and then, a p-type impurity is implanted into the first semiconductor film, the third semiconductor film, and the fourth semiconductor film using the second resist as a mask.

According to this configuration, in the process of making the n-type thin film transistor, the first resist, the second resist, and the third resist, which were formed using a single photomask, can be used as masks when conducting the n-type impurity implantation process where an n-type impurity is implanted into the first semiconductor film of the n-type thin film transistor, and the p-type impurity implantation process where a p-type impurity is implanted into the first semiconductor film. As a result, there is no need to use two separate masks to conduct the n-type impurity implantation process and the p-type impurity implantation process, and only a single photomask needs to be used. Therefore, the number of processes required to manufacture an n-type thin film transistor can be reduced, and the manufacturing cost can significantly be lowered.

Also, in the process of making the another n-type thin film transistor, the photomask used to make the n-type thin film transistor is used to form the first resist, the second resist, and the third resist, and these resists, which resists can be used as masks when conducting the n-type impurity implantation process where an n-type impurity is implanted into the third semiconductor film of the another n-type thin film transistor, and the p-type impurity implantation process where a p-type impurity is implanted into the third semiconductor film. As a result, in the process of making the n-type thin film transistor and the another thin film transistor, the impurity implantations can be conducted simultaneously using a single photomask.

Further, in the process of making the capacitance, the first resist, the second resist, and the third resist, which resists were formed using the photomask used to make the n-type thin film transistor, can be used as masks when conducting the p-type impurity implantation process in which a p-type impurity is implanted into the fourth semiconductor film of the capacitance. As a result, in the process of making the n-type thin film transistor and the capacitance, the impurity implantation processes can be conducted simultaneously using a single photomask.

The second method for manufacturing the semiconductor of the present invention may further include the step of conducting an insulating film formation process in which, after the p-type impurity implantation process, the second resist is removed and an insulating film is formed over the first semiconductor film, the second semiconductor film, the third semiconductor film, and the fourth semiconductor film.

According to this configuration, an insulating film is formed after the p-type impurity implantation. Therefore, when ashing, for example, is conducted to remove the first resist and the third resist, and a p-type impurity is implanted into the first semiconductor film, the third semiconductor film, and the fourth semiconductor film using the second resist as a mask, where the second resist has a thickness that has been reduced by the ashing, the p-type impurity can be sufficiently implanted into the first semiconductor film, the third semiconductor film, and the fourth semiconductor film without causing the problem of the p-type impurity implantation into the second semiconductor film due to the reduced thickness of the second resist.

In the second method for manufacturing the semiconductor device, a gray-tone mask or a half-tone mask may be used as the photomask.

According to this configuration, because an exposure process with different exposure radiation amounts can easily be conducted on the photosensitive resin, the exposure radiation control on the photosensitive resin becomes easy.

In the second method for manufacturing the semiconductor device of the present invention, the photosensitive resin may be an acrylic photosensitive resin.

In the second method of manufacturing the semiconductor device of the present invention, the first semiconductor film and the second semiconductor film may be formed of polysilicon.

### EFFECTS OF THE INVENTION

According to the present invention, the number of manufacturing processes required to make the n-type thin film transistor can be reduced, and the cost can significantly be lowered.

### BRIEF DESCRIPTION OF THE DRAWINGS

FIG. 1 is a cross-sectional view illustrating the configuration of a semiconductor device according to Embodiment 1 of the present invention.

FIG. 2 is a cross-sectional view illustrating the method of manufacturing the semiconductor device according to Embodiment 1 of the present invention.

FIG. 3 is a cross-sectional view illustrating the method of manufacturing the semiconductor device according to Embodiment 1 of the present invention.

FIG. 4 is a cross-sectional view illustrating the method of manufacturing the semiconductor device according to Embodiment 1 of the present invention.

FIG. 5 is a cross-sectional view illustrating the method of manufacturing the semiconductor device according to Embodiment 1 of the present invention.

FIG. 6 is a cross-sectional view illustrating the method of manufacturing the semiconductor device according to Embodiment 1 of the present invention.

FIG. 7 is a cross-sectional view illustrating the method of manufacturing the semiconductor device according to Embodiment 1 of the present invention.

FIG. 8 is a cross-sectional view illustrating the method of manufacturing the semiconductor device according to Embodiment 1 of the present invention.

FIG. 9 is a plan view schematically showing the configuration of the photomask used for exposure in the method for manufacturing the semiconductor device according to Embodiment 1 of the present invention.

FIG. 10 is a cross-sectional view illustrating the method for manufacturing the semiconductor device according to Embodiment 1 of the present invention.

FIG. 11 is a cross-sectional view illustrating the method for manufacturing the semiconductor device according to Embodiment 1 of the present invention.

FIG. 12 is a cross-sectional view illustrating the method for manufacturing the semiconductor device according to Embodiment 1 of the present invention.

FIG. 13 is a cross-sectional view illustrating the configuration of a semiconductor device according to Embodiment 2 of the present invention.

FIG. 14 is a cross-sectional view illustrating the method for manufacturing the semiconductor device according to Embodiment 2 of the present invention.

FIG. 15 is a cross-sectional view illustrating the method for manufacturing the semiconductor device according to Embodiment 2 of the present invention.

FIG. 16 is a cross-sectional view illustrating the method for manufacturing the semiconductor device according to Embodiment 2 of the present invention.

FIG. 17 is a cross-sectional view illustrating the method for manufacturing the semiconductor device according to Embodiment 2 of the present invention.

FIG. 18 is a cross-sectional view illustrating the method for manufacturing the semiconductor device according to Embodiment 2 of the present invention.

FIG. 19 is a cross-sectional view illustrating the method for manufacturing the semiconductor device according to Embodiment 2 of the present invention.

FIG. 20 is a cross-sectional view illustrating the method for manufacturing the semiconductor device according to Embodiment 2 of the present invention.

FIG. 21 is a plan view schematically showing the configuration of a photomask used for exposure in the method for manufacturing the semiconductor device according to Embodiment 2 of the present invention.

FIG. 22 is a cross-sectional view illustrating the method for manufacturing the semiconductor device according to Embodiment 2 of the present invention.

FIG. 23 is a cross-sectional view illustrating the method for manufacturing the semiconductor device according to Embodiment 2 of the present invention.

FIG. 24 is a cross-sectional view illustrating the method for manufacturing the semiconductor device according to Embodiment 2 of the present invention.

FIG. 25 is a cross-sectional view illustrating the method for manufacturing a semiconductor device according to a modification example of an embodiment of the present invention.

FIG. 26 is a cross-sectional view illustrating the method for manufacturing the semiconductor device according to the modification example of an embodiment of the present invention.

FIG. 27 is a cross-sectional view illustrating the method for manufacturing the semiconductor device according to the modification example of an embodiment of the present invention.

FIG. 28 is a cross-sectional view illustrating the method for manufacturing the semiconductor device according to the modification example of an embodiment of the present invention.

### DETAILED DESCRIPTION OF EMBODIMENTS

Embodiments of the present invention are described below with reference to figures. The present invention, however, is not limited to embodiments described below.

### Embodiment 1

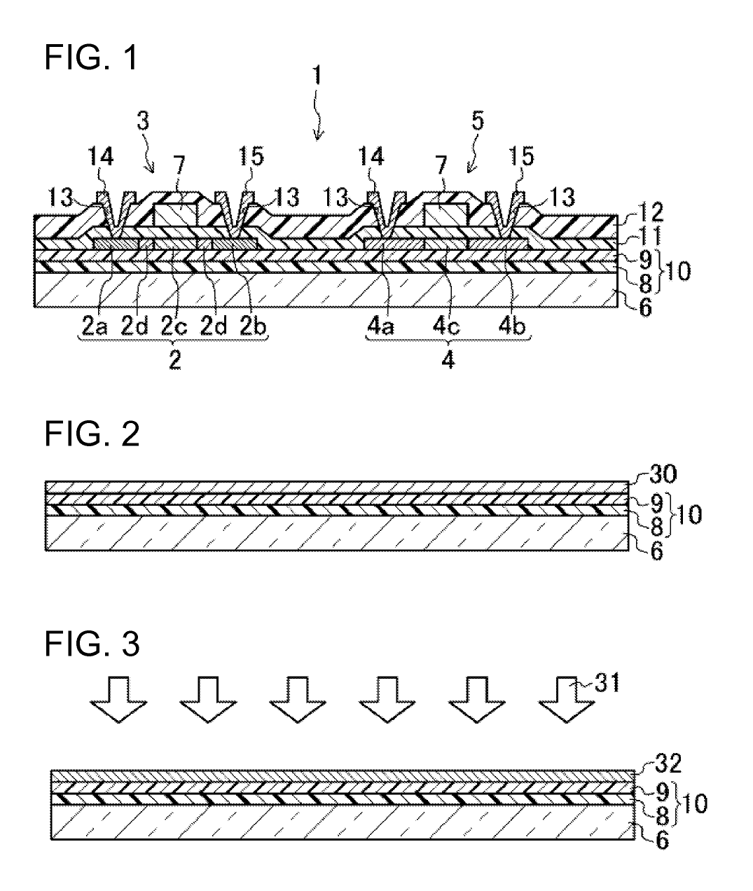

FIG. 1 is a cross-sectional view illustrating the configuration of a semiconductor device according to Embodiment 1 of the present invention.

As shown in FIG. 1, a semiconductor device 1 includes a CMOS, and the CMOS includes an n-type TFT 3 including the first semiconductor film 2 and a p-type TFT 5 including a second semiconductor film 4. That is, the semiconductor device 1 includes the n-type TFT 3 and the p-type TFT 5.

The n-type TFT 3 and the p-type TFT 5 function as, for example, active elements of driver circuits such as a gate driver and a source driver provided in the liquid crystal display device.

The n-type TFT 3 and the p-type TFT 5 each has a top gate type configuration where a gate electrode 7 is disposed on the side opposite from a glass substrate 6 of the first semiconductor film 2 and the second semiconductor film 4.

Also, on the glass substrate 6, a base insulating film 10 constituted of a first insulating film 8, which is made of a silicon nitride film or the like, and of a second insulating film 9, which is made of a silicon oxide film or the like, is formed. On the base insulating film 10, the first semiconductor film 2 and the second semiconductor film 4 are formed to a thickness of, for example, 50 nm or the like. The first semiconductor film 2 and the second semiconductor film 4 are apart by a prescribed distance.

The first semiconductor film 2 and the second semiconductor film 4 are constituted of, for example, a crystalline silicon film (semiconductor film) made of polysilicon or the like.

In the first semiconductor film 2 and in the second semiconductor film 4, a pair of high-concentration impurity regions, which are source regions 2a and 4a and drain regions 2b and 4b, are formed, sandwiching channel regions 2c and 4c, respectively. The channel regions 2c and 4c each contains boron, a p-type impurity, to control the threshold voltage.

The source region 2a and the drain region 2b of the first semiconductor film 2 contains phosphorus, which is an n-type impurity. Also, the source region 4a and the drain region 4b of the second semiconductor film 4 contains boron, which is a p-type impurity.

In the first semiconductor film 2, LDD (Lightly doped drain) regions 2d, which are impurity regions containing phosphorus n-type impurity, are disposed adjacent to the channel region 2c, between the source region 2a and drain region 2b. As shown in FIG. 1, there are two LDD regions 2d.

On the first semiconductor film 2 and the second semiconductor film 4, a gate insulating film 11 is disposed, covering the first semiconductor film 2 and the second semiconductor film 4. The gate insulating film 11 is formed of silicon oxide or the like, for example.

Over each of the channel regions 2c and 4c of the first semiconductor film 2 and the second semiconductor film 4, a gate electrode 7 is formed through the gate insulating film 11. The gate electrode 7 is formed of, for example, Al, Ta, or MoW alloy, or Cr.

Also, an interlayer insulating film 12 is formed to cover the gate insulating film 11 and the gate electrode 7. The interlayer insulating film 12 is formed of silicon nitride or the like, for example. Also, the gate insulating film 11 and the interlayer insulating film 12 are formed to a thickness of 400 nm, for example.

Over the source regions 2a and 4a and the drain regions 2b and 4b, contact holes 13 are formed to run through the gate insulating film 11 and the interlayer insulating film 12. The contact holes 13 are filled with a conductive material such as Al, Ta, MoW alloy or Cr. On the interlayer insulating film 12, source electrodes 14 connected to the source region 2a or 4a are formed, and drain electrodes 15 connected to drain region 2b or 4b are formed via the contact holes 13.

The source electrodes 14 and drain electrodes 15 are formed to a thickness of 380 nm, for example, and the source electrodes 14 and the drain electrodes 15 are formed of the above-mentioned conductive material.

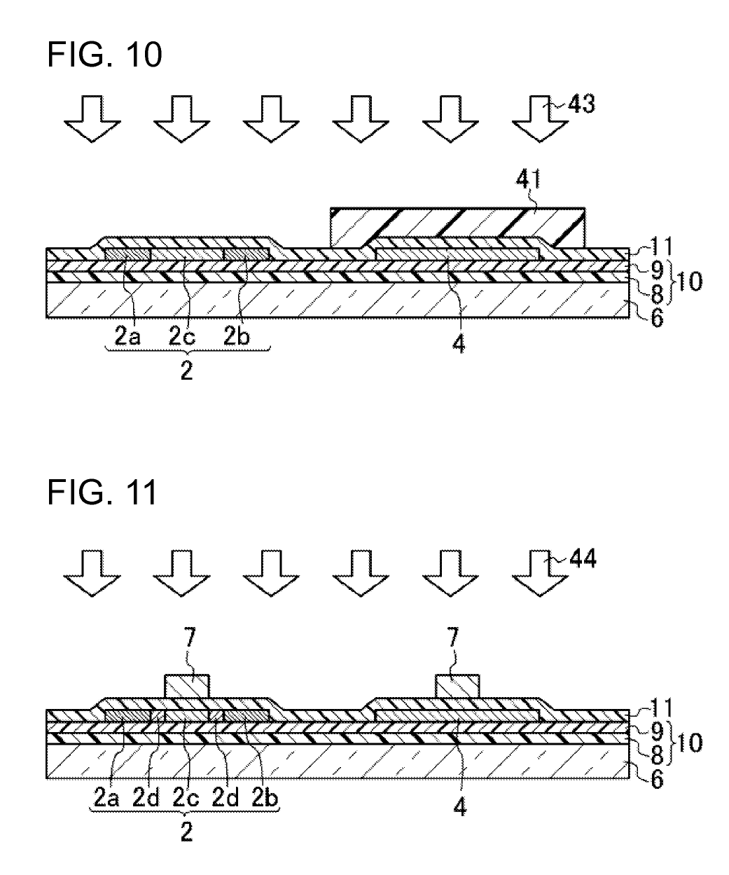

Next, a method for manufacturing the semiconductor device is described. FIG. 2 to FIG. 8 are cross-sectional views illustrating the method for manufacturing the semiconductor device according to Embodiment 1 of the present invention. FIG. 9 is a plan view schematically showing the configuration of the photomask used for exposure in the method for manufacturing the semiconductor device according to Embodiment 1 of the present invention. FIG. 10 to FIG. 12 are cross-sectional views illustrating the method for manufacturing the semiconductor device according to Embodiment 1 of the present invention.

<Semiconductor Film Formation Process>

First, as shown in FIG. 2, on one side of a glass substrate 6, a base insulating film 10 constituted of a first insulating film 8 made of a silicon nitride film or the like and a second insulating film 9 made of a silicon oxide film or the like are formed by, for example, sputtering or a like method.

Next, on the base insulating film 10, an amorphous silicon film 30, which is non-crystalline silicon film, by, for example, the CVD or a like method.

Next, as shown in FIG. 3, laser light 31 is radiated to the amorphous silicon film 30 to crystallize the amorphous silicon film 30 and to form a polysilicon film (crystalline silicon film) 32, which is a semiconductor film, over the glass substrate 6.

The laser light 31 to be used may be an excimer laser or a solid-state laser such as XeCl (308 nm), XeF (351 nm), KrF (248 nm), or the like. From the perspective of reducing the surface roughness of the polysilicon film 32, prior to the laser light 31 radiation, any naturally formed oxide film formed on the amorphous silicon film 30 is preferably removed. Also, from a similar perspective, the laser light 31 is preferably radiated in an inert atmosphere such as nitride or the like.

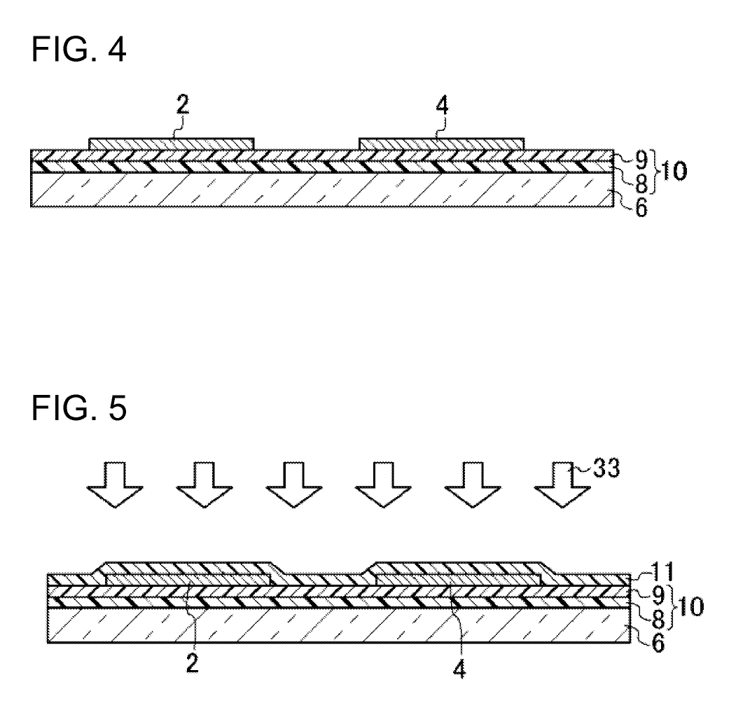

Next, as shown in FIG. 4, the polysilicon film 32 is patterned into island shapes by photolithography to form a first semiconductor film 2 and a second semiconductor film 4 on the glass substrate 6.

<Gate Insulating Film Formation Process>

Next, as shown in FIG. 5, over the entire substrate on which the first semiconductor film 2 and the second semiconductor film 4 are formed, a silicon nitride film, for example, is deposited by the plasma CVD (Chemical Vapor Deposition) method to form a gate insulating film 11 to a thickness of about 4000 Å.

<P-Type Impurity Implantation Process>

Next, as shown in FIG. 5, boron, which is a p-type impurity, is implanted into the entirety of the first semiconductor film 2 and the second semiconductor film 4. Arrows 33 shown in FIG. 5 indicate the direction of the boron implantation.

For the boron implantation, the ion doping method or the like is used. Also, the accelerating voltage is set to 15 to 30 kV, and the dose is set to 5×10¹¹ to 6×10¹² cm⁻², for example.

<Photosensitive Resin Formation Process>

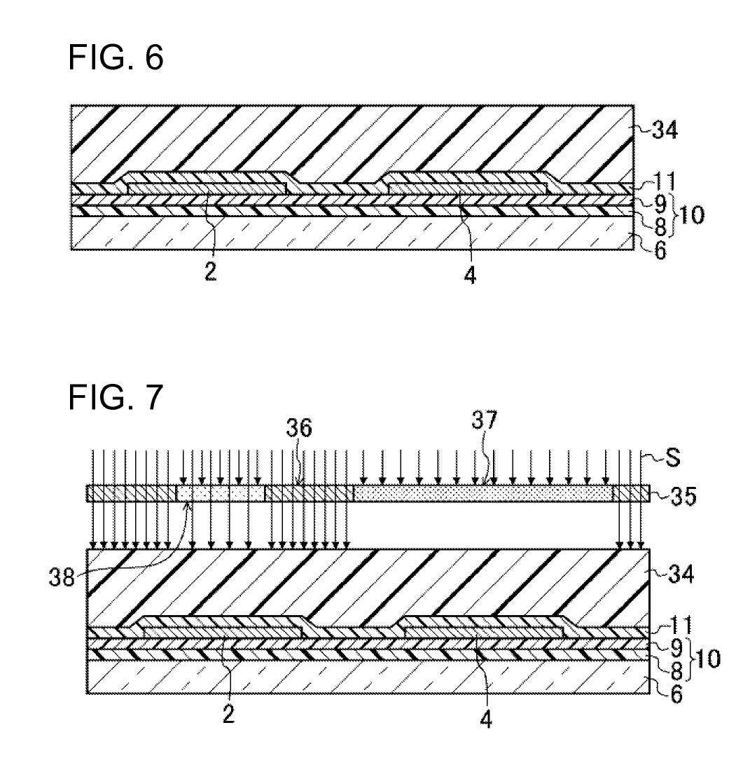

Next, as shown in FIG. 6, a photosensitive resin (e.g. acrylic photosensitive resin) 34 of positive type (where exposed portions are dissolved in the developing process and removed), for example, is applied over the glass substrate 6 by the spin coating method to a thickness of about 1 to 3 μm to cover the first semiconductor film 2 and the second semiconductor film 4.

<Exposure and Resist Formation Processes>

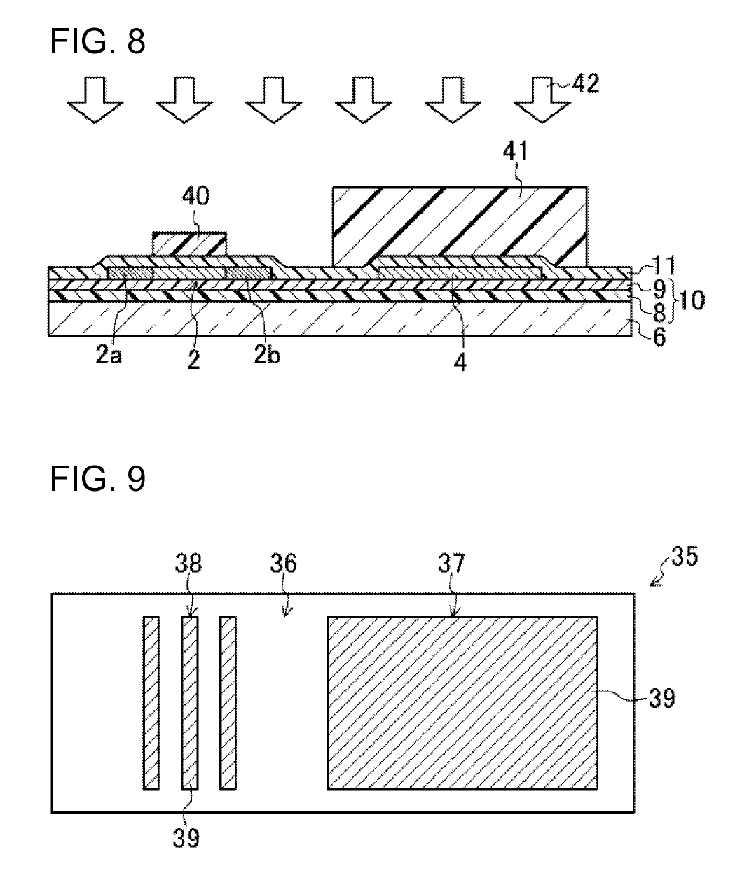

Next, as shown in FIG. 7, an exposure process is conducted with the amounts of exposure radiation to the photosensitive resin 34 controlled using a photomask 35, and then a developing process is conducted to the photosensitive resin 34 that has been subjected to the exposure process. As a result, as shown in FIG. 8, a first resist 40 and a second resist 41, which have different thicknesses, are formed simultaneously.

The first resist 40 is formed over the first semiconductor film 2, and has a smaller thickness (e.g. about 0.5 to 1.5 μm) than the second resist 41 (e.g. about 1 to 3 μm). The second resist 41 is formed over the second semiconductor film 4.

As shown in FIG. 7, in this embodiment, a half-tone mask or a gray-tone mask is used as the photomask 35 to control the amounts of exposure radiation to the photosensitive resin 34 when conducting the exposure process (the half-tone exposure process or the gray-tone exposure process).

That is, a half-tone mask or a gray-tone mask having segments of different levels of transmittance is used as the photomask 35, and an exposure process is conducted on the photosensitive resin 34 through this photomask 35.

In such an exposure process, photosensitive resin 34 can easily be exposed to different exposure radiation amounts. Consequently, the amount of exposure radiation to the photosensitive resin 34 can readily be controlled. Also, as shown in FIG. 8, when the photosensitive resin 34 that underwent such an exposure process is subjected to a developing process, a first resist 40 and a second resist 41, which have different thicknesses, can be formed of the same material simultaneously.

In this embodiment, as shown in FIG. 9, a photomask having a transmissive segment 36 that transmit light and a light-shielding segment 37 that blocks light, as well as a semi-transmissive segment 38 that transmits light of mid-level intensity is used as the photomask 35.

In the light-shielding segment 37, a light-shielding layer 39 made of, for example, Cr or the like is formed to cover the entire light-shielding segment 37, and in the semi-transmissive segment 38, a plurality of light-shielding layers 39 are arranged in stripes. In the semi-transmissive segment 38, the light-shielding layers 39 are 1.0 μm to 2.0 μm wide each, for example, and the space between adjacent light-shielding layers 39 is 1.0 μm to 2.0 μm, for example.

Thus, because the stripe pattern formed by the light-shielding layers 39 of the semi-transmissive segment 38 is fine, the exposure radiation coming through the semi-transmissive segment 38 does not expose the photosensitive resin 34 in a stripe pattern. Instead, the light exposure radiation is reduced by the light-shielding layer 39, and the photosensitive resin 34 is exposed evenly with a less intensive radiation than under the transmissive segment 36.

In FIG. 9, the transmissive segment 36, the light-shielding segment 37, and the semi-transmissive segment 38 are shown schematically for easier understanding of the configuration of the photomask 35. However, the photomask 35 is actually configured such that when it is at a prescribed position facing the photosensitive resin 34, the semi-transmissive segment 38 is disposed over the channel region 2c and the region that constitutes the LDD region 2d of the n-type TFT 3 (i.e., the first semiconductor film 2). Also, the photomask 35 is formed such that the light-shielding segment 37 is disposed over the region of the p-type TFT 5 (i.e., the second semiconductor film 4).

When an exposure process is conducted on the photosensitive resin 34, as shown in FIG. 7, the photomask 35 is positioned to face the photosensitive resin 34 in a prescribed manner as described above, and then ultraviolet ray S is radiated through the photomask 35 from the side of the photomask 35 that is not facing the glass substrate 6, to expose the photosensitive resin 34 through the photomask 35.

Next, a developing process is conducted on the photosensitive resin 34. That is, the photosensitive resin 34 is immersed in the developing solution to dissolve and remove the portion of the photosensitive resin 34 that was exposed to the ultraviolet ray S. The entire substrate is then washed.

At this time, the portion of the photosensitive resin 34 that was shielded by the light-shielding segment 37 and therefore not exposed is reserved to form a second resist 41. Also, the portion of the photosensitive resin 34 that was exposed through the semi-transmissive segment 38 is reserved to form a first resist 40.

<N-Type Impurity Implantation Process>

Next, as shown in FIG. 8, phosphorus, which is an n-type impurity, is implanted into the first semiconductor film 2 using the photoresists 40 and 41 as masks. Arrows 42 in FIG. 8 indicate the direction of the phosphorus implantation.

For the phosphorus implantation, the ion doping method or the like is used, where, for example, the accelerating voltage is set to 40 to 60 kV and the dose is set to 5×10¹⁴ to 5×10¹⁵ cm⁻². By conducting the phosphorus implantation, as shown in FIG. 8, a source region 2a and a drain region 2b, which are high concentration impurity regions, are formed in the first semiconductor film 2 of the n-type TFT 3.

<P-Type Impurity Implantation Process>

First, as shown in FIG. 10, first resist 40 is removed by ashing or a like method. At this time, ashing is conducted also on the second resist 41 as well as on the first resist 40. This way, as shown in FIG. 10, the second resist 41 is preserved although its thickness is reduced, because the second resist 41 had a larger thickness than the first resist 40.

Next, using the second resist 41 as a mask, boron, which is a p-type impurity, is implanted into the first semiconductor film 2. Arrows 43 in FIG. 10 indicate the direction of the boron implantation. For the boron implantation, the ion doping method or the like is used, where, for example, the accelerating voltage is set to 15 to 30 kV and the dose is set to 5×10¹¹ to 6×10¹² cm⁻². By conducting the boron implantation, as shown in FIG. 10, a channel region 2c is formed in the first semiconductor film 2 of the n-type TFT 3.

Thus, in this embodiment, in the process of making the n-type TFT 3, the process of implanting an n-type impurity into the first semiconductor film 2 (i.e., source region 2a and drain region 2b of the n-type TFT 3) and the process of implanting a p-type impurity into the first semiconductor film 2 (i.e., channel region 2c of the n-type TFT 3) can be done using the first resist 40 and the second resist 41 made using a single photomask 35. As a result, there is no need to use separate masks for the n-type impurity implantation process and for the p-type impurity implantation process, and the processes need only a single photomask 35. Therefore, the number of manufacturing processes required to make the n-type TFT 3 can be reduced, and a significant cost reduction can be realized.

<Gate Electrode Formation Process>

Next, as shown in FIG. 11, the second resist 41 covering the second semiconductor film 4 is removed by ashing or a like method, and gate electrodes 7 are patterned on the gate insulating film 11 on the side opposite from the glass substrate 6 by, for example, photolithography and dry etching, or a like method, to cover the channel regions 2c and 4c of the first semiconductor film 2 and the second semiconductor film 4.

<LDD Region Formation Process>

Next, as shown in FIG. 11, phosphorus, which is an n-type impurity, is implanted into the first semiconductor film 2 using the gate electrode 7 as a mask. Arrows 44 in FIG. 11 indicate the direction of the phosphorus implantation.

For the phosphorus implantation, the ion doping method or the like is used, where, for example, the accelerating voltage is set to 40 to 90 kV and the dose is set to 5×10¹² to 1×10¹⁴ cm⁻². By conducting the phosphorus implantation, as shown in FIG. 11, LDD regions 2d are formed in the first semiconductor film 2, and, as a result, the first semiconductor film 2 is now constituted of the source region 2a, the drain region 2b, the channel region 2c, and the LDD regions 2d.

<Second Semiconductor Film Formation Process>

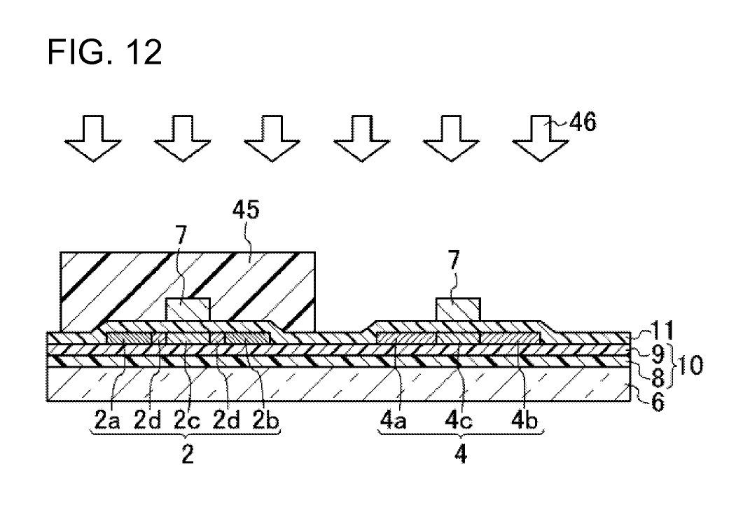

Next, as shown in FIG. 12, a photoresist 45 is formed over the gate insulating film 11 and the gate electrode 7 to cover the first semiconductor film 2, and boron, which is a p-type impurity, is implanted into the second semiconductor film 4 using the photoresist 45 and the gate electrode 7 as masks. Arrows 46 in FIG. 11 indicate the direction of the boron implantation.

For the boron implantation, the ion doping method or the like is used, where, for example, the accelerating voltage is set to 60 to 90 kV and the dose is set to 1×10¹⁴ to 5×10¹⁵ cm⁻². By conducting the boron implantation, as shown in FIG. 12, a source region 4a, a drain region 4b, and a channel region 4c are formed in the second semiconductor film 4, where the channel region 4c is sandwiched between the source region 4a and the drain region 4b. Thus, the second semiconductor film 4 is now constituted of the source region 4a, the drain region 4b, and the channel region 4c.

<Source Electrode and Drain Electrode Formation Process>

Next, the photoresist 45 is removed by ashing or a like method, and an interlayer insulating film 12 is formed to cover the gate electrodes 7 and the gate insulating film 11. Then, contact holes 13 are formed to run through the gate insulating film 11 and the interlayer insulating film 12, over the source regions 2a and 4a and the drain regions 2b and 4b by etching or a like method.

Next, in the contact holes 13 and on the interlayer insulating film 12, source electrodes 14 and drain electrodes 15 are formed. The source electrodes 14 and the drain electrodes 15 are formed, for example, by photolithography and dry etching or a like method. The source electrodes 14 are each connected to the source region 2a or 4a and the drain electrodes 15 are each connected to the drain region 2b or 4b through the contact hole 13.

Thus, the semiconductor device 1 shown in FIG. 1 is manufactured.

### Embodiment 2

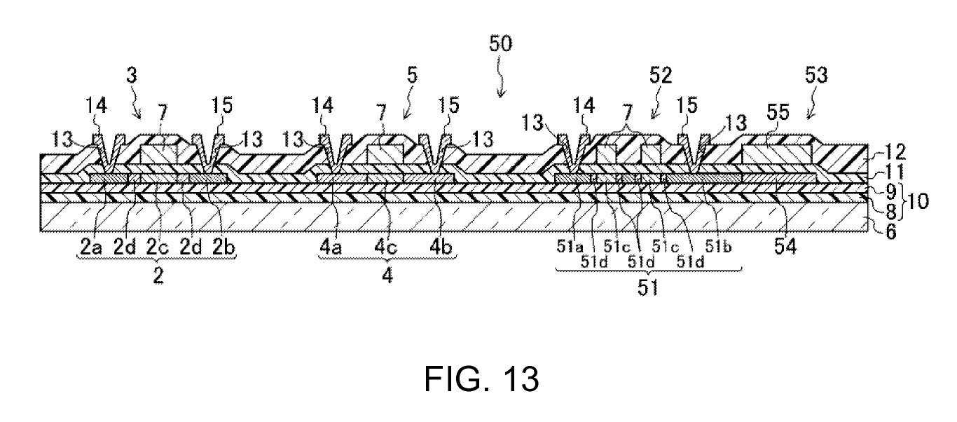

Next, Embodiment 2 of the present invention is described. FIG. 13 is a cross-sectional view illustrating the configuration of the semiconductor device according to Embodiment 2 of the present invention. For constituting items similar to Embodiment 1, same reference characters are used and their descriptions are omitted.

As shown in FIG. 13, a semiconductor device 50 includes another n-type TFT (hereinafter referred to as “TFT”) 52 having a third semiconductor film 51, and a capacitance 53 having a fourth semiconductor film 54 and disposed adjacent to the TFT 52, as well as the above-mentioned n-type TFT 3 and p-type TFT 5.

TFT 52 functions, for example, as a pixel switching element provided in a liquid crystal display device, and the capacitance 53 functions, for example, as a storage capacitance provided in a liquid crystal display device.

TFT 52 is configured in the same manner as the above-mentioned n-type TFT 3. TFT 52 has the top gate type configuration, where the gate electrode 7 is disposed on one side of the third semiconductor film 51, away from the glass substrate 6.

That is, TFT 52 includes: a glass substrate 6; a base insulating film 10 formed on the glass substrate 6 and constituted of a first insulating film 8 and a second insulating film 9; and a third semiconductor film 51 formed on the base insulating film 10 to a thickness of, for example, 50 nm or the like. The third semiconductor film 51 is constituted of, for example, a crystalline silicon film (semiconductor film) made of polysilicon or the like.

The third semiconductor film 51 includes a source region 51a and a drain region 51b, which are a pair of high-concentration impurity regions and are disposed to sandwich two channel regions 51c. The source region 51a and the drain region 51b contain phosphorus, which is an n-type impurity. The channel region 51c contains boron, which is a p-type impurity for controlling the threshold voltage.

The third semiconductor film 51 includes LDD regions 51d, which are impurity regions disposed between the source region 51a and the drain region 51b and adjacent to the channel regions 51c. LDD regions 51d contain phosphorus, which is an n-type impurity. As shown in FIG. 13, four LDD regions 51d are formed.

On the third semiconductor film 51, a gate insulating film 11 is disposed to cover the third semiconductor film 51. Over the channel regions 51c of the third semiconductor film 51, gate electrodes 7 are formed via the gate insulating film 11. Also, an interlayer insulating film 12 is formed to cover the gate insulating film 11 and the gate electrodes 7. Also, over the source region 51a and the drain region 51b, contact holes 13 are formed to run through the gate insulating film 11 and the interlayer insulating film 12. These contact holes 13 are filled with a conductive material. On the interlayer insulating film 12, a source electrode 14 connected to the source region 51a and a drain electrode 15 connected to the drain region 51b through the respective contact holes 13 are formed.

The capacitance 53 is constituted of a fourth semiconductor film 54 containing boron, which is a p-type impurity, a gate insulating film 11 formed on the fourth semiconductor film 54, and a capacitor electrode 55 formed on the gate insulating film 11. As shown in FIG. 13, the fourth semiconductor film 54 is integrally formed with the third semiconductor film 51.

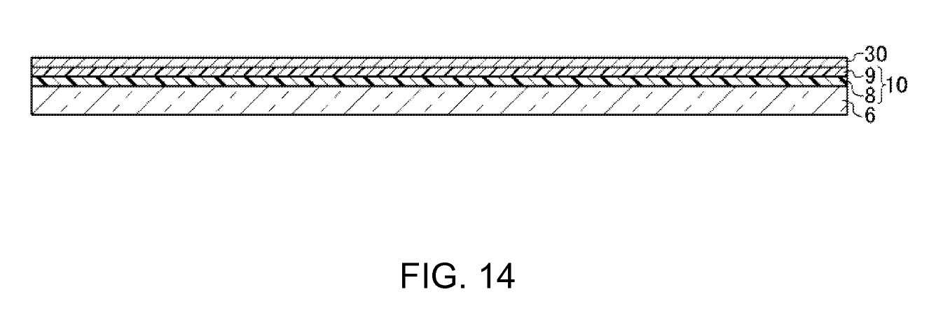

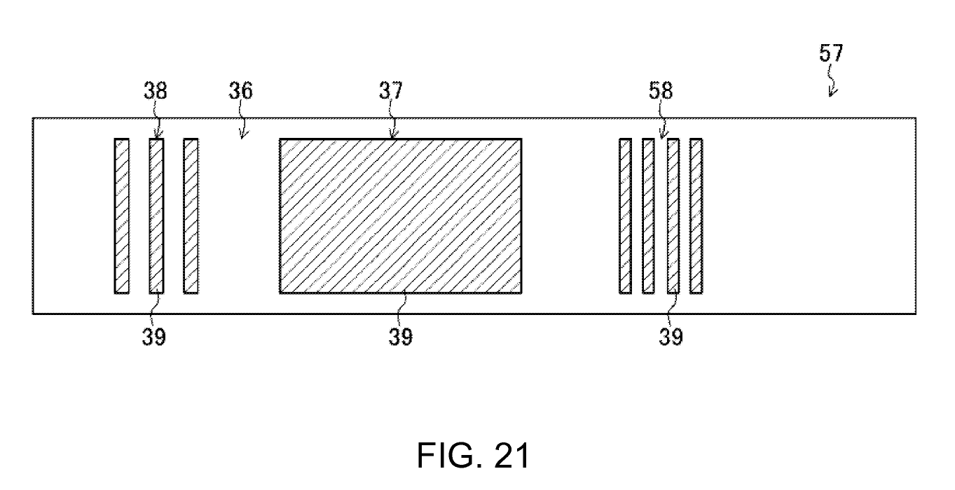

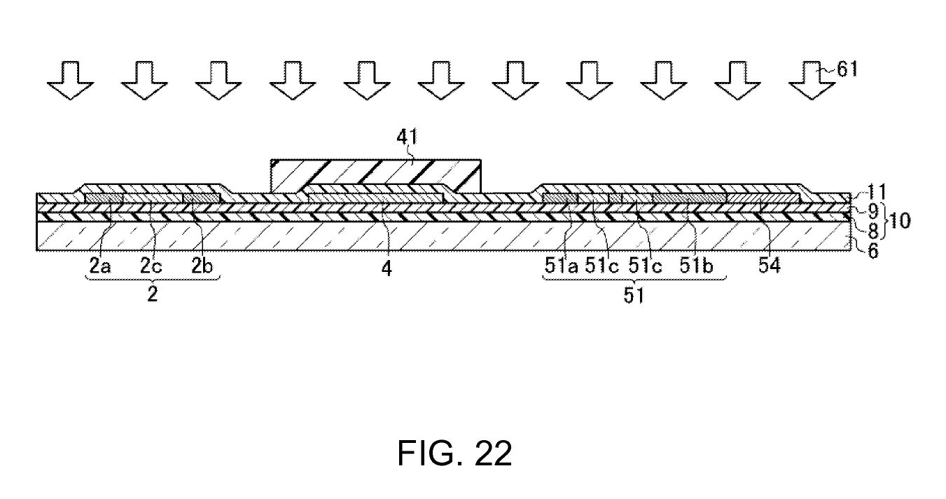

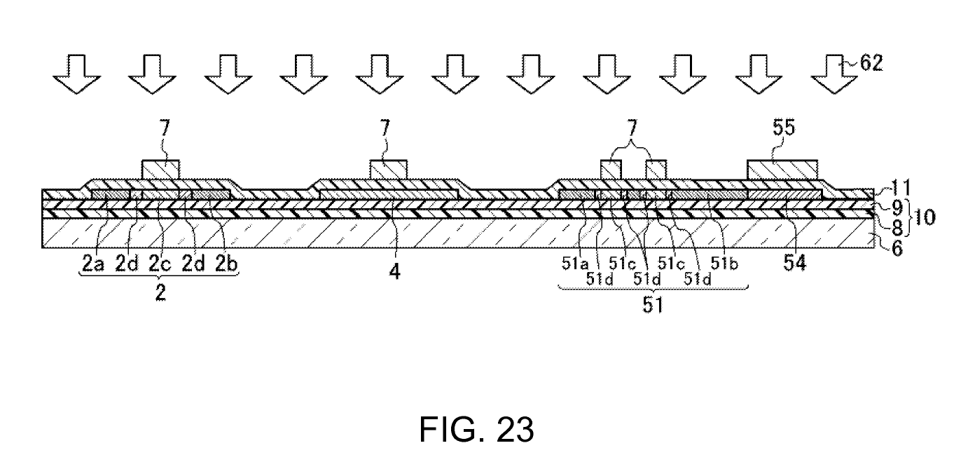

Next, a method for manufacturing the semiconductor device is described. FIG. 14 to FIG. 20 are cross-sectional views illustrating the method for manufacturing the semiconductor device according to Embodiment 2 of the present invention. FIG. 21 is a plan view schematically showing the configuration of a photomask used for exposure in the method for manufacturing the semiconductor device according to Embodiment 2 of the present invention. FIG. 22 to FIG. 24 are cross-sectional views illustrating the method for manufacturing the semiconductor device according to Embodiment 2 of the present invention.

<Semiconductor Film Formation Process>

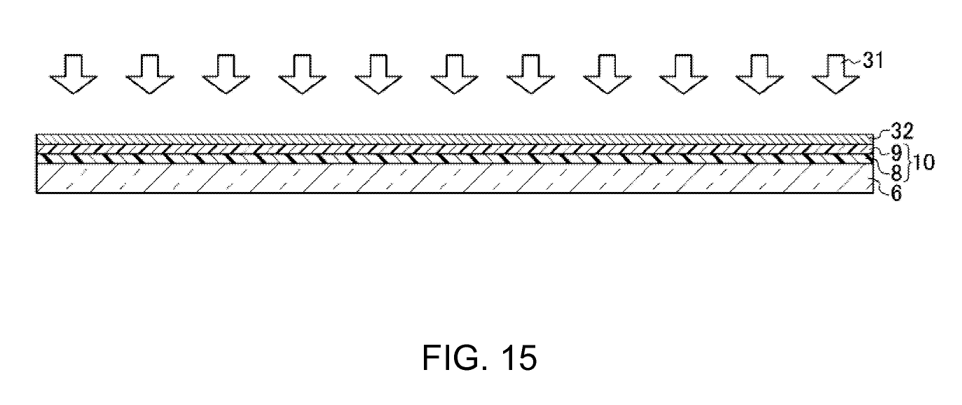

First, as shown in FIG. 14, on one side of the glass substrate 6, a base insulating film 10 constituted of a first insulating film 8 and a second insulating film 9 is formed. Then, an amorphous silicon film 30 is formed on the base insulating film 10. Next, as shown in FIG. 15, laser light 31 is radiated to the amorphous silicon film 30 to crystallize the amorphous silicon film 30 and to form a polysilicon film (crystalline silicon film) 32, which is a semiconductor film, on the glass substrate 6.

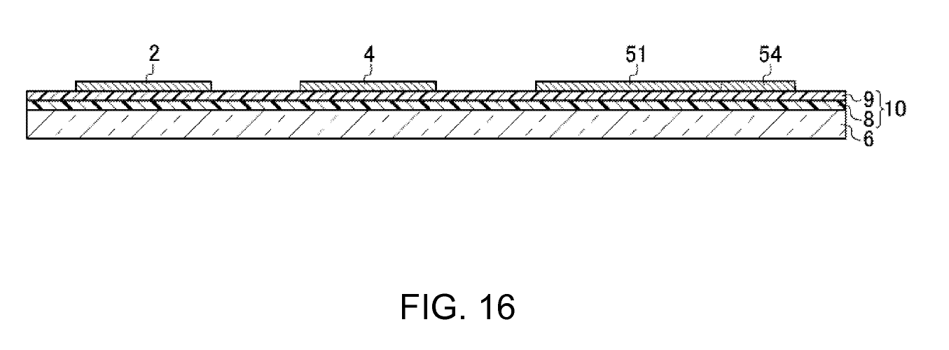

Next, as shown in FIG. 16, the polysilicon film 32 is patterned into island shapes by photolithography to form a first semiconductor film 2, a second semiconductor film 4, a third semiconductor film 51, and a fourth semiconductor film 54 on the glass substrate 6.

<Gate Insulating Film Formation Process>

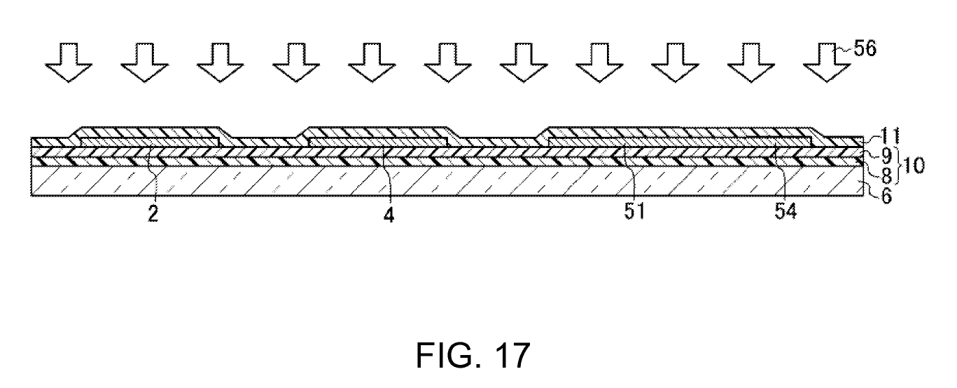

Next, as shown in FIG. 17, over the entire substrate where the first semiconductor film 2, the second semiconductor film 4, the third semiconductor film 51, and the fourth semiconductor film 54 are formed, a silicon nitride film or the like, for example, is deposited by the plasma CVD (Chemical Vapor Deposition) method to form a gate insulating film 11 to a thickness of about 4000 Å.

<P-Type Impurity Implantation Process>

Next, as shown in FIG. 17, boron, a p-type impurity, is implanted into the entirety of the first semiconductor film 2, the second semiconductor film 4, the third semiconductor film 51, and the fourth semiconductor film 54. Arrows 56 in FIG. 17 indicate the direction of the boron implantation.

<Photosensitive Resin Formation Process>

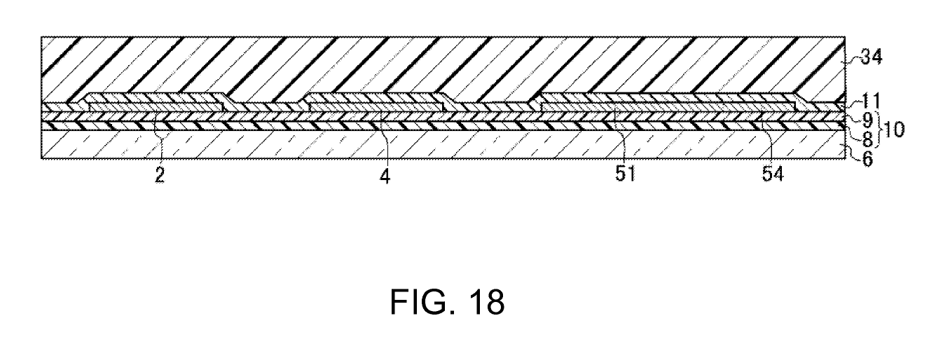

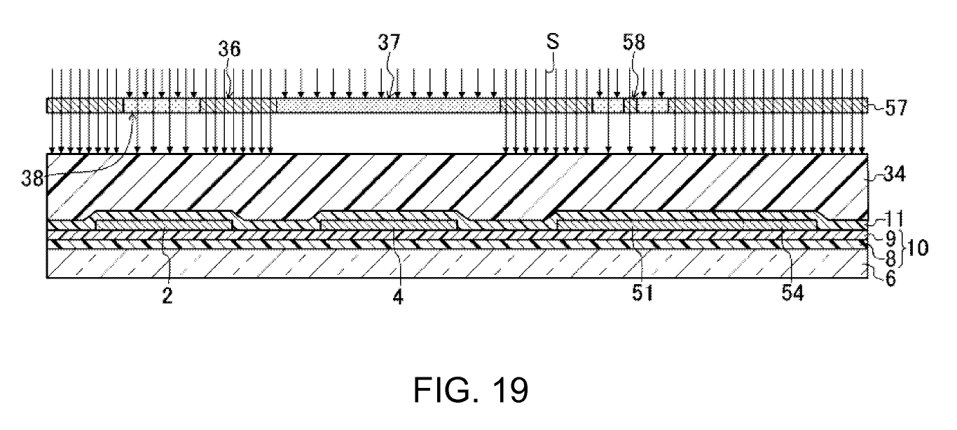

Next, as shown in FIG. 18, in a similar manner as described above with reference to FIG. 6, a positive photosensitive resin (e.g. acrylic photosensitive resin) 34, for example, is formed to a thickness of 1 to 3 μm by the spin coating method on the glass substrate 6 to cover the first semiconductor film 2, the second semiconductor film 4, the third semiconductor film 51, and the fourth semiconductor film 54.

<Exposure and Resist Formation Process>

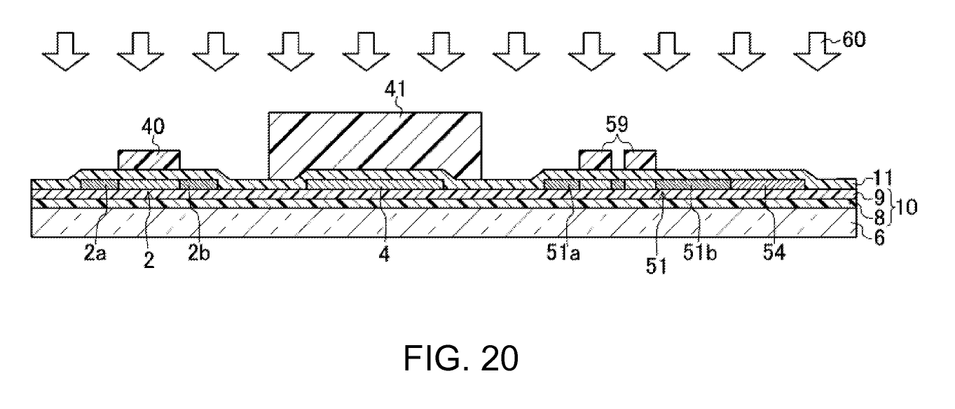

Next, as shown in FIG. 19, in a similar manner as described above with reference to FIG. 7, an exposure process is conducted on the photosensitive resin 34 with the amount of exposure radiation controlled using the photomask 57, and then a developing process is conducted on the photosensitive resin 34, which has been subjected to the exposure process, to simultaneously form, as shown in FIG. 20, a first resist 40, a second resist 41, and third resists 59, where all the resists have different thicknesses. The third resists 59 are formed over the third semiconductor film 51, and have a smaller thickness than the second resist 41 (e.g. about 0.5 to 1.5 μm).

Here, in this embodiment, as in Embodiment 1, a half-tone mask or a gray-tone mask is used as the photomask 57 in the exposure process, as shown in FIG. 19, to control the amount of the exposure radiation to the photosensitive resin 34.

By conducting such an exposure process, the photosensitive resin 34 can be exposed with different amounts of exposure radiation. Consequently, as shown in FIG. 20, when the photosensitive resin 34 that underwent such an exposure process is subjected to a developing process, a first resist 40, a second resist 41, and a third resist 59, all having different thicknesses, can be formed simultaneously, out of the same material.

As shown in FIG. 21, in this embodiment, similar to Embodiment 1 described above, a photomask having a semi-transmissive segment 58 that transmits light of mid-level intensity as well as a transmissive segment 36 that transmits light, a light-shielding segment 37 that completely blocks light, and a semi-transmissive segment 38 that transmits light of mid-level intensity is used as the photomask 57. Like the semi-transmissive segment 38 described above, the semi-transmissive segment 58 has a plurality of light-shielding layers 39 arranged in stripes.

Because the stripe pattern formed by the light-shielding layers 39 of the semi-transmissive segment 58 is fine, the exposure radiation coming through the semi-transmissive segment 58 does not expose the photosensitive resin 34 in a stripe pattern. Instead, the light exposure radiation is reduced by the light-shielding layer 39, and the photosensitive resin 34 is exposed evenly with a less intensive radiation than under the transmissive segment 36.

The photomask 57 is configured such that when it is disposed at a prescribed position facing the photosensitive resin 34, the semi-transmissive segment 58 is positioned over the region in which a channel region 51c and an LDD region 51d of TFT 52 (i.e., third semiconductor film 51) will be formed.

As shown in FIG. 19, when an exposure process is conducted on the photosensitive resin 34, the photomask 57 is placed to the prescribed position to face the photosensitive resin 34. Then, ultraviolet light S is projected to the photosensitive resin 34 through the photomask 57, from the side of the photomask 57 that is not facing the glass substrate 6. This way, the photosensitive resin 34 is exposed through the photomask 57.

Next, a developing process is conducted on the photosensitive resin 34. Here, the portion of the photosensitive resin 34 that was covered by the light-shielding segment 37 and therefore not exposed is preserved to form a second resist 41. Also, the portion of the photosensitive resin 34 exposed through the semi-transmissive segments 38 and 58 is preserved to form a first resist 40 and a third resist 59.

<N-Type Impurity Implantation Process>

Next, as shown in FIG. 20, phosphorus, which is an n-type impurity, is implanted into the first semiconductor film 2 and the third semiconductor film 51 using the first resist 40, the second resist 41, and the third resist 59 as masks. Arrows 60 shown in FIG. 20 indicate the direction of the phosphorus implantation. As shown in FIG. 20, once phosphorus is implanted, a source region 2a and a drain region 2b, which are high-concentration impurity regions, are formed in the first semiconductor film 2 of the n-type TFT 3, and a source region 51a and a drain region 51b, which are high-concentration impurity region, are formed in the third semiconductor film 51 of the TFT 52.

<P-Type Impurity Implantation Process>

First, as shown in FIG. 22, the first resist 40 and the third resist 59 are removed by ashing or a like method. At this time, ashing is conducted on the second resist 41 also, in the same manner as ashing conducted on the first resist 40 and the third resist 59. As a result, as shown in FIG. 22, the second resist 41 is preserved although its thickness is reduced, because the second resist 41 had a larger thickness than the first resist 40 or the third resist 59.

Next, boron, which is a p-type impurity, is implanted into the first semiconductor film 2, the third semiconductor film 51, and the fourth semiconductor film 54 using the second resist 41 as a mask. Arrows 61 in FIG. 22 indicate the direction of the boron implantation.

Then, as shown in FIG. 22, once boron is implanted, a channel region 2c is formed in the first semiconductor film 2, and channel regions 51c are formed in the third semiconductor film 51. Also, at the same time when the channel regions 2c and 51c are formed, a fourth semiconductor film 54 containing boron, a p-type impurity, is formed.

Thus, in this embodiment, as in Embodiment 1 described above, in the process of making the n-type TFT 3, the first resist 40, the second resist 41, and the third resist 59, which resists were formed using a single photomask 57, can be used as masks when implanting an n-type impurity into the source region 2a and the drain region 2b of the n-type TFT 3, and when implanting a p-type impurity into the channel region 2c of the n-type TFT 3.

Also, in the process of making the TFT 52, the first resist 40, the second resist 41, and the third resist 59, which resists were formed using the photomask 57 used to form the n-type TFT 3, can be used as masks when conducting the n-type impurity implantation process where an n-type impurity is implemented into the third semiconductor film 51 (i.e., the source region 2a and the drain region 2b of TFT 52), and the p-type impurity implantation process where a p-type impurity is implanted into the third semiconductor film 51 (i.e., the channel region 2c of TFT 52). Consequently, in the process of making the n-type TFT 3 and TFT 52, a single photomask 57 can be used to conduct the impurity implantation processes simultaneously.

Further, in the process of making the capacitance 53, the first resist 40, the second resist 41, and the third resist 59, which resists were formed using the photomask 57 used to make the n-type TFT 3, can be used as masks when conducting the p-type impurity implantation process in which a p-type impurity is implanted into the fourth semiconductor film 54. Consequently, in the process of making the n-type TFT 3 and the capacitance 53, impurity implantation processes can be conducted simultaneously using a single photomask, which is the photomask 57.

<Gate Electrode Formation Process>

Next, as shown in FIG. 23, the second resist 41 covering the second semiconductor film 4 is removed by ashing or a like method. Gate electrodes 7 are patterned on the gate insulating film 11 on the side opposite from the glass substrate 6 by, for example, the photolithography, dry etching, or a like method, to cover the channel regions 2c, 4c, and 51c of the first semiconductor film 2, the second semiconductor film 4, and the third semiconductor film 51. A capacitor electrode 55 is formed to cover the fourth semiconductor film 54.

<LDD Region Formation Process>

Next, as shown in FIG. 23, phosphorus, which is an n-type impurity, is implanted into the first semiconductor film 2 and the third semiconductor film 51 using the gate electrodes 7 as masks. Arrows 62 in FIG. 23 indicate the direction of the phosphorus implementation. Then, as shown in FIG. 23, because of the phosphorus implantation, LDD regions 2d are formed in the first semiconductor film 2, to make the first semiconductor film 2 constituted of the source region 2a, the drain region 2b, the channel region 2c, and the LDD regions 2d. Similarly, LDD regions 51d are formed in the third semiconductor film 51 to make the third semiconductor film 51 to be constituted of the source region 51a, the drain region 51b, the channel region 51c, and the LDD regions 51d.

<Second Semiconductor Film Formation Process>

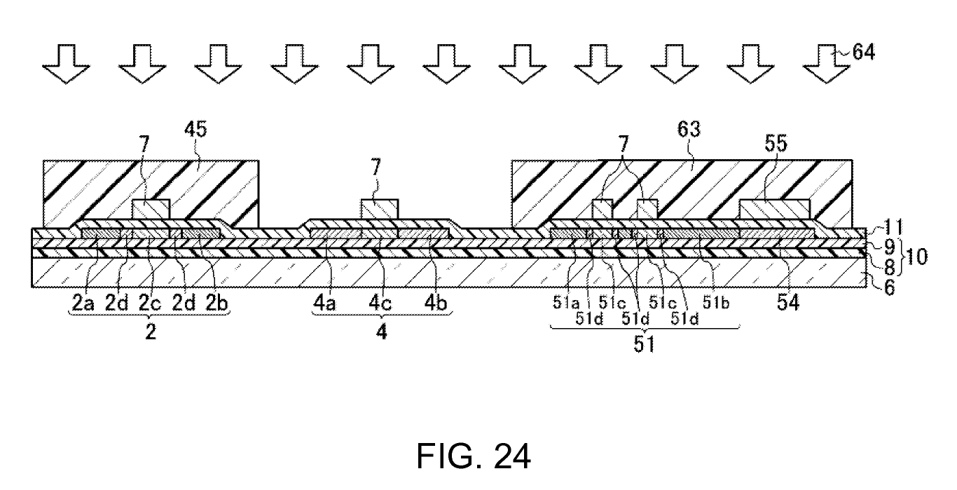

Next, as shown in FIG. 24, resists 45 and 63 are formed over the gate insulating film 11, the gate electrodes 7, and the capacitor electrode 55 to cover the first semiconductor film 2, the third semiconductor film 51, and the fourth semiconductor film 54. Then, using the resists 45 and 63 and the gate electrodes 7 as masks, boron, a p-type impurity, is implanted into the second semiconductor film 4. Arrows 64 shown in FIG. 24 indicate the direction of the boron implementation.

Then, as shown in FIG. 24, because of the boron implantation, the source region 4a, the drain region 4b, and the channel region 4c, which is interposed between the source region 4a and drain region 4b, are formed in the second semiconductor film 4, to make the second semiconductor film 4 constituted of the source region 4a, the drain region 4b, and the channel region 4c.

<Source Electrode and Drain Electrode Formation Process>

Next, resists 45 and 63 are removed by ashing or a like method, and an interlayer insulating film 12 that covers the gate electrodes 7, the capacitor electrode 55, and the gate insulating film 11 is formed. Then, over the source regions 2a, 4a, and 51a and the drain regions 2b, 4b, and 51b, contact holes 13 are formed to run through the gate insulating film 11 and the interlayer insulating film 12 by etching or a like method.

Next, source electrodes 14 and drain electrodes 15 are formed inside the contact holes 13 and on the interlayer insulating film 12. Through the contact holes 13, the source electrodes 14 are connected to source regions 2a, 4a, and 51a, and the drain electrodes 15 are connected to drain regions 2b, 4b, and 51b.

Thus, the semiconductor device 50 shown in FIG. 13 is manufactured.

The above-mentioned embodiment may be modified as described below.

In Embodiment 2 described above, the first resist 40, the second resist 41, and the third resist 59 are formed after the gate insulating film 11 is formed, and then the source region 2a, the drain region 2b, and the channel region 2c are formed using the first resist 40, the second resist 41, and the third resist 59 as masks. However, the source region 2a, the drain region 2b, and the channel region 2c may be formed before the gate insulating film 11 is formed, using the first resist 40, the second resist 41, and the third resist 59 as masks.

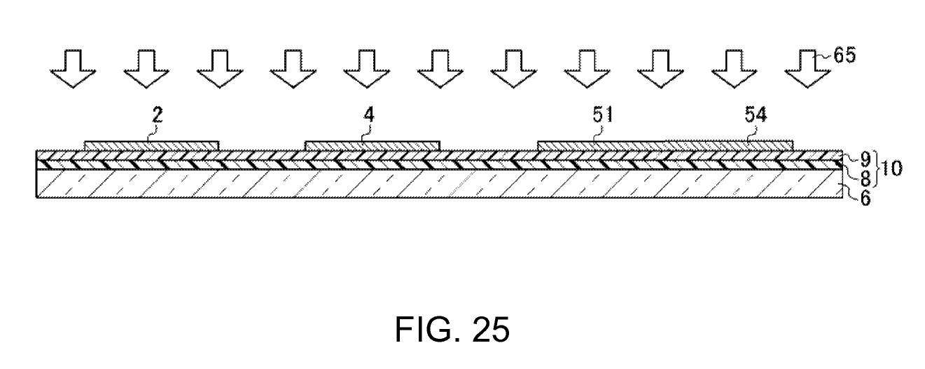

More specifically, after the semiconductor layer formation process which is described above with reference to FIG. 14 to FIG. 16, as shown in FIG. 25, the p-type impurity implantation process, in which boron, a p-type impurity, is implanted into the first semiconductor film 2, the second semiconductor film 4, the third semiconductor film 51, and the fourth semiconductor film 54, is conducted before the gate insulating film 11 is formed. Arrows 65 in FIG. 25 indicate the direction of the boron implantation.

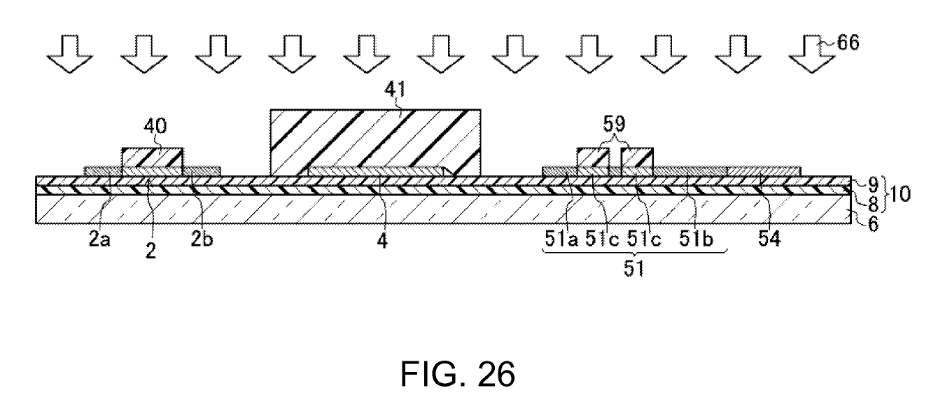

Next, after the exposure and resist formation processes, which are described above with reference to FIG. 18 and FIG. 19, as shown in FIG. 26, phosphorus, an n-type impurity, is implanted into the first semiconductor film 2 and the third semiconductor film 51, in the same manner as in the n-type impurity implantation process described with reference to FIG. 20. Arrows 66 in FIG. 26 indicate the direction of the phosphorus implantation. As shown in FIG. 26, once phosphorus is implanted, a source region 2a and a drain region 2b, which are high-concentration impurity regions, are formed in the first semiconductor film 2 of the n-type TFT 3, and a source region 51a and a drain region 51b, which are high-concentration impurity regions, are formed in the third semiconductor film 51 of the TFT 52.

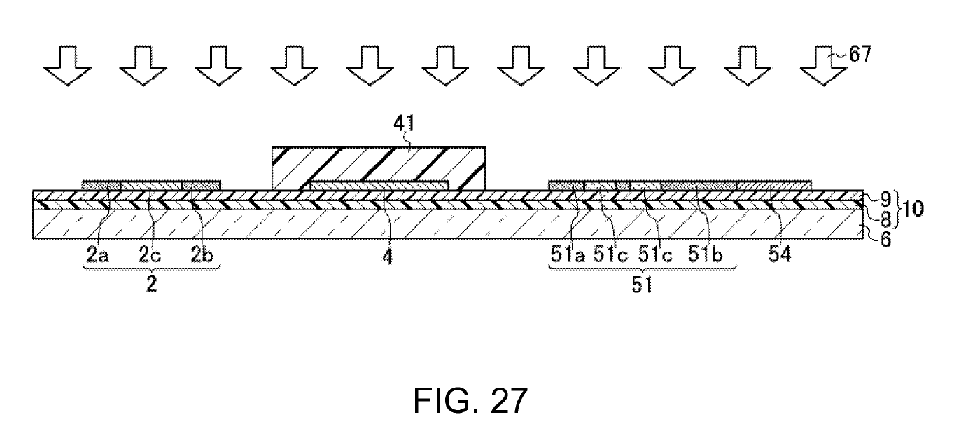

Next, as shown in FIG. 27, in a similar manner with the p-type impurity implantation process described above with reference to FIG. 22, the first resist 40 and the third resist 59 are removed by ashing or a like method, and boron, a p-type impurity, is implanted into the first semiconductor film 2, the third semiconductor film 51, and the fourth semiconductor film 54. Arrows 67 in FIG. 27 indicate the direction of the boron implantation. By conducting the boron implantation, as shown in FIG. 27, a channel region 2c is formed in the first semiconductor film 2, and a channel region 51c is formed in the third semiconductor film 51. Also, at the same time when the channel regions 2c and 51c are formed, a fourth semiconductor film 54 containing boron, a p-type impurity, is formed.

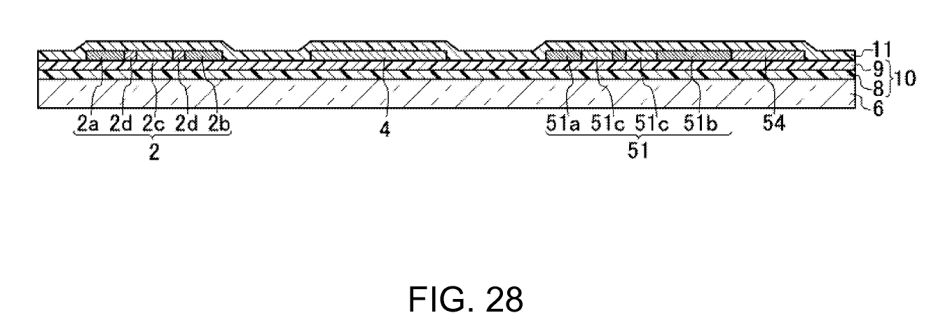

Next, in a similar manner as in the gate insulating film formation process described above with reference to FIG. 17, after removing the second resist 41 covering the second semiconductor film 4 by ashing or a like method, as shown in FIG. 28, a gate insulating film 11 is formed over the entire substrate on which the first semiconductor film 2, the second semiconductor film 4, the third semiconductor film 51, and the fourth semiconductor film 54 are formed.

That is, after the p-type impurity implantation process, the second resist is removed and a gate insulating film 11 is formed over the first semiconductor film 2, second semiconductor film 4, third semiconductor film 51, and the fourth semiconductor film 54.

Then, the gate electrode and LDD region formation process, the second semiconductor film formation process, and the source electrode and drain electrode formation process are conducted as described above for Embodiment 2, to manufacture a semiconductor device 50 shown in FIG. 13.

As shown in FIG. 22 and FIG. 27, in the p-type impurity implantation process, because ashing is conducted on the second resist 41 as well as on the first resist 40 and the third resist 59, the thickness of the second resist 41 is reduced.

Consequently, the functionality of the second resist 41 as a mask lowers. Therefore, when boron implantation is conducted using the second resist 41 as a mask, a portion of the boron can pass through the second resist 41 and be implanted into the second semiconductor film 4.

In order to avoid such a problem, the accelerating voltage for doping needs to be reduced. However, as shown in FIG. 22, if the accelerating voltage is reduced when the gate insulating film 11 is formed over the first semiconductor film 2, the second semiconductor film 4, the third semiconductor film 51, and the fourth semiconductor film 54, boron may not be sufficiently implanted into the first semiconductor film 2, the third semiconductor film 51, and the fourth semiconductor film 54.

On the other hand, as shown in FIG. 27, when the gate insulating film 11 is not formed over the first semiconductor film 2, the second semiconductor film 4, the third semiconductor film 51, and the fourth semiconductor film 54, boron is sufficiently implanted into the first semiconductor film 2, third semiconductor film 51, and the fourth semiconductor film 54 even if the accelerating voltage for doping is reduced.

That is, because the gate insulating film 11 is formed after the p-type impurity implantation, even if the first resist 40 and the third resist 59 are removed by ashing, for example, and a p-type impurity is implanted into the first semiconductor film 2, the third semiconductor film 51, and the fourth semiconductor film 54 using the second resist 41 whose thickness has been reduced, the p-type impurity can sufficiently be implanted into the first semiconductor film 2, the third semiconductor film 51, and the fourth semiconductor film 54 without the undesirable p-type impurity implantation into the second semiconductor film 4 due to the reduced thickness of the second resist 41.

In the case shown in FIG. 27, the accelerating voltage is set to 5 to 20 kV, and the dose is set to 5×10¹¹ to 1×10¹³ cm⁻², for example.

Similarly, in Embodiment 1 described above, the first resist 40 and the second resist 41 are formed after the gate insulating film 11 is formed, and the source region 2a, drain region 2b, and the channel region 2c are formed using the first resist 40 and the second resist 41 as masks. However, the source region 2a, the drain region 2b, and the channel region 2c may be formed using the first resist 40 and the second resist 41 as masks before the gate insulating film 11 is formed. Also in this case, a similar effect illustrated in FIG. 25 to FIG. 28 can be obtained.

Although boron is used as the p-type impurity in this embodiment, the present invention is not limited to such. P-type impurities other than boron, such as aluminum, may also be used as the p-type impurity.

Although boron is implanted with the ion doping method in this embodiment, the present embodiment is not limited to such. Boron may be implanted in other known methods, such as the ion implantation method or the like, for example.

Also, in this embodiment, a plurality of light-shielding layers 39 are arranged in stripes in the semi-transmissive segments 38 and 58 of the photomasks 35 and 57, but the present invention is not limited to such. The semi-transmissive segments 38 and 58 may include light-shielding layers 39 arranged in a net-like pattern.

### INDUSTRIAL APPLICABILITY

An application example of the present invention is a semiconductor device equipped with switching elements such as thin film transistors and the like.

### DESCRIPTION OF REFERENCE CHARACTERS

1 semiconductor device
2 first semiconductor film
3 n-type TFT (n-type thin film transistor)
4 second semiconductor film
5 p-type TFT (p-type thin film transistor)
6 glass substrate (substrate)
11 gate insulating film (insulating film)
34 photosensitive resin
35 photomask
40 first resist
41 second resist
51 third semiconductor film
52 TFT (another n-type thin film transistor)
53 capacitance
54 fourth semiconductor film
57 photomask
59 third resist

1. A method for manufacturing a semiconductor device having, on a substrate, an n-type thin film transistor including a first semiconductor film and a p-type thin film transistor including a second semiconductor film, comprising:
conducting a semiconductor film formation process in which said first semiconductor film and said second semiconductor film are formed on said substrate;
conducting a photosensitive resin formation process in which a photosensitive resin is formed over said substrate to cover said first semiconductor film and said second semiconductor film;
conducting an exposure process in which controlled amounts of exposure radiation are projected to said photosensitive resin using a photomask;
conducting a resist formation process in which a developing process is performed on said photosensitive resin that has been subjected to said exposure process, to form a first resist over said first semiconductor film and to form a second resist over said second semiconductor film;
conducting an n-type impurity implantation process in which an n-type impurity is implanted into said first semiconductor film using said first resist and said second resist as masks; and
conducting a p-type impurity implantation process in which said first resist is removed, and then, a p-type impurity is implanted into said first semiconductor film using said second resist as a mask.

2. The method for manufacturing the semiconductor device according to claim 1, further comprising a step of conducting an insulating film formation process in which, after said p-type impurity implantation process, said second resist is removed and an insulating film is formed on said first semiconductor film and on said second semiconductor film.

3. The method for manufacturing the semiconductor device according to claim 1, wherein said photomask is a gray-tone mask or half-tone mask.

4. The method for manufacturing the semiconductor according to claim 1, wherein said photosensitive resin is an acrylic photosensitive resin.

5. The method for manufacturing the semiconductor according to claim 1, wherein said first semiconductor film and said second semiconductor film are formed of polysilicon in said semiconductor film formation process.

6. A method for manufacturing a semiconductor device having, on a substrate, an n-type thin film transistor including a first semiconductor film, a p-type thin film transistor including a second semiconductor film, another n-type thin film transistor including a third semiconductor film, and a capacitance including a fourth semiconductor film, comprising:
conducting a semiconductor film formation process in which said first semiconductor film, said second semiconductor film, said third semiconductor film, and said fourth semiconductor film are formed on said substrate;
conducting a photosensitive resin formation process in which a photosensitive resin is provided over said substrate to cover said first semiconductor film, said second semiconductor film, said third semiconductor film, and said fourth semiconductor film;
conducting an exposure process in which controlled amounts of exposure radiation are projected to said photosensitive resin using a photomask;
conducting a resist formation process in which a developing process is performed on said photosensitive resin that has been subjected to said exposure process, to form a first resist on said first semiconductor film, to form a second resist on said second semiconductor film, and to form a third resist on said third semiconductor film;
conducting an n-type impurity implantation process in which an n-type impurity is implanted into said first semiconductor film and said third semiconductor film using said first resist, said second resist, and said third resist as masks; and
conducting a p-type impurity implantation process in which said first resist and said third resist are removed, and then, a p-type impurity is implanted into said first semiconductor film, said third semiconductor film, and said fourth semiconductor film using said second resist as a mask.

7. The method for manufacturing the semiconductor device according to claim 6, further comprising the step of conducting an insulating film formation process after said p-type impurity implantation process, in which said second resist is removed, and an insulating film is formed over said first semiconductor film, said second semiconductor film, said third semiconductor film, and said fourth semiconductor film.

8. The method for manufacturing the semiconductor device according to claim 6, wherein said photomask is a gray-tone mask or a half-tone mask.

9. The method for manufacturing the semiconductor device according to claim 6, wherein said photosensitive resin is an acrylic photosensitive resin.

10. The method for manufacturing the semiconductor device according to claim 6, wherein said first semiconductor film, said second semiconductor film, said third semiconductor film, and said fourth semiconductor film are formed of polysilicon in said semiconductor film formation process.
